(19) United States
(12) Patent Application Publication
(10) Pub. No.: US 2010/0212716 A1
(43) Pub. Date: Aug. 26, 2010

(54) Solar radiation collection using dichroic surface

(76) Inventors: Scott Lerner, Portland, OR (US); John P. Whitlock, Lebanon, OR (US); Paul J. Benning, Corvallis, OR (US)

Correspondence Address: HEWLETT-PACKARD COMPANY;Intellectual Property Administration, 3404 E. Harmony Road, Mail Stop 35, FORT COLLINS, CO, 80528, US

(21) Appl. No.: 12/378,826

(22) Filed: Feb. 20, 2009

(51) Int. Cl. H01L 31/052; H01L 21/00; G01J 1/44

(52) U.S. Cl. 136/246; 438/69; 250/206; 257/E21.001

(57) ABSTRACT

A solar radiation collection system includes a first photovoltaic cell, a second photovoltaic cell, and an optical medium, the optical medium. The optical medium has a first zone configured to transmit radiation incident on the first zone to the first cell, a second zone disposed adjacent a side of the first zone, and a first dichroic surface configured to reflect a first portion of radiation incident on the second zone such that the reflected radiation is directed toward the first cell by internal reflection and to transmit a second portion of radiation incident on the second zone to the second cell.

### BACKGROUND

The field of photovoltaics generally relates to multi-layer materials that convert sunlight directly into DC electrical power. The basic mechanism for this conversion is the photovoltaic (or photoelectric) effect. In the United States, photovoltaic (PV) devices are popularly known as solar cells or PV cells.

Solar cells are typically configured as a cooperating sandwich of p-type and n-type semiconductors, in which the n-type semiconductor material (on one “side” of the sandwich) exhibits an excess of electrons, and the p-type semiconductor material (on the other “side” of the sandwich) exhibits an excess of holes, each of which signifies the absence of an electron. Near the p-n junction between the two materials, valence electrons from the n-type layer move into neighboring holes in the p-type layer, creating a small electrical imbalance inside the solar cell. This results in an electric field in the vicinity of the junction.

When an incident photon excites an electron in the cell into the conduction band, the excited electron becomes unbound from the atoms of the semiconductor, creating a free electron/hole pair. Because, as described above, the p-n junction creates an electric field in the vicinity of the junction, electron/hole pairs created in this manner near the junction tend to separate and move away from junction, with the electron moving toward the n-type side, and the hole moving toward the p-type side of the junction. This creates an overall charge imbalance in the cell, so that if an external conductive path is provided between the two sides of the cell, electrons will move from the n-type side back to the p-type side along the external path, creating an electric current. In practice, electrons may be collected from at or near the surface of the n-type side by a conducting grid that covers a portion of the surface, while still allowing sufficient access into the cell by incident photons.

Such a photovoltaic structure, when appropriately located electrical contacts are included and the cell (or a series of cells) is incorporated into a closed electrical circuit, forms a working PV device. As a standalone device, a single conventional solar cell is not sufficient to power most applications. As a result, solar cells are commonly arranged into PV modules, or “strings,” by connecting the front of one cell to the back of another, thereby adding the voltages of the individual cells together in electrical series. Typically, a significant number of cells are connected in series to achieve a usable voltage. The resulting DC current then may be fed through an inverter, where it is transformed into AC current at an appropriate frequency, which is chosen to match the frequency of AC current supplied by a conventional power grid. The resulting voltage can also be used to charge batteries and energize low voltage circuitry.

One type of solar cell is a crystalline silicon PV cell, in which two layers of silicon that have been doped with different types of atoms form the p-type and n-type semiconductor layers. Silicon-based PV cells can reach efficiencies of around 20%, but can be relatively fragile and difficult to transport and install. Another type of solar cell that has been developed for commercial use is a “thin-film” PV cell, in which several thin layers of inorganic material are deposited sequentially on a substrate to form a working cell. This is typically accomplished through evaporation (such as vacuum deposition) or sputtering. In comparison to crystalline silicon PV cells, thin-film PV cells require less light-absorbing material to create a working cell, and thus can reduce processing costs. Furthermore, inorganic thin-film cells have exhibited efficiencies approaching 20%, which rivals or exceeds the efficiencies of most crystalline cells. A third type of solar cell is a thin-film cell based on organic polymers of various types. These cells are relatively lightweight, inexpensive and flexible.

Thin-film PV materials may be deposited either on rigid glass substrates, or on flexible substrates. Glass substrates are relatively inexpensive, but suffer from various shortcomings, such as a need for substantial floor space for processing equipment and material storage, specialized heavy duty handling equipment, a high potential for substrate fracture, increased shipping costs due to the weight and fragility of the glass, and difficulties in installation. In contrast, roll-to-roll processing of thin flexible substrates allows for the use of compact, less expensive vacuum systems, and of non-specialized equipment that already has been developed for other thin-film industries. PV cells based on thin flexible substrate materials also require comparatively low shipping costs, and exhibit a greater ease of installation than cells based on rigid substrates. On the other hand, thin-film substrates, such as thin sheets of stainless steel, are typically more expensive than glass substrates.

### BRIEF DESCRIPTION OF THE DRAWINGS

FIG. 1 is a side elevational view of a prior art solar radiation collection system.

FIG. 2 is a side elevational view of an improved solar radiation collection system, in accordance with an embodiment of the present disclosure.

FIG. 3 is a side elevational view of an embodiment of a solar radiation collection system, in accordance with another embodiment of the present disclosure.

FIG. 4 is a side elevational view of another embodiment of a solar radiation collection system, in accordance with yet another embodiment of the present disclosure.

FIG. 5 is a side elevational view of another embodiment of a solar radiation collection system, in accordance with still another embodiment of the present disclosure.

FIG. 6 is a side elevational view of a solar radiation collection system including an optical concentrating element.

FIG. 7 is a side elevational view of a solar radiation collection system including a plurality of substantially similar collection modules.

FIG. 8 is a top view of a plurality of solar radiation collectors disposed on a substrate.

FIG. 9 is a top view of an embodiment of a plurality of solar radiation collectors disposed on a substrate.

FIG. 10 is a flow diagram illustrating a method of manufacturing a solar radiation collection system.

FIG. 11 if a flow diagram illustrating a method of collecting solar radiation.

### DETAILED DESCRIPTION

The present disclosure provides for absorption and conversion of a wide spectrum of incident radiation to electricity. Regardless of which type of PV cell is used, the photovoltaic materials of a particular cell are typically effective in a particular range of solar radiation wavelengths. If the photon energy is less than the band gap energy, which is the difference between the valence and conduction bands, no electron hole pairs are generated. For any photon energy greater than the band gap, the electron will be excited to the highest energy and then will move to the lowest energy state which is at the bottom of the valence band, before being used by an external circuit. Any energy greater than the band gap will be lost as heat. An effective wavelength range for crystalline silicon-based PV cells may be from 300-600 nanometers (nm), whereas some inorganic thin-film PV cells may be most effective in the wavelength range from 600-1200 nm. Other PV cells, such as thin-film cells based on organic materials, may be particularly effective for ultraviolet radiation in the wavelength range from 100-400 nm. Because different types of PV cells are responsive to different ranges of solar radiation, using just one particular type of cell in a given solar device does not generally make optimal use of the full range of incident solar wavelengths.

FIG. 1 is a side elevational view of a prior art solar radiation concentrating system. In the system of FIG. 1, which is generally indicated at 10′, a PV cell 12′ is disposed underneath an optical medium 14′ having a predetermined index of refraction. Reflective surfaces 16′ are disposed along side portions of the optical medium. As indicated in the drawing, incident solar rays either pass through the medium and directly to cell 12′, or are reflected from one of surfaces 16′. Reflected rays reaching the top boundary of the optical medium at more than a particular critical angle to its normal are internally reflected and redirected toward cell 12′. As is well known, this critical angle is given by:

$${θ}_{c} = arcsin ( {n}_{2} / {n}_{1} ) ,$$

where n₂ is the index of refraction of the less dense medium (in this case, typically air or vacuum) and n₁ is the index of refraction of more dense optical medium 14′. In this manner, the amount of solar radiation reaching cell 12′ is increased, and greater electricity production per unit surface area of PV material can be achieved.

Despite the possible advantages of the prior art system shown in FIG. 1 and described above, it still suffers from the shortcoming that the central PV cell 12′ must be of a particular type, and therefore generally will be sensitive only to solar radiation falling within a particular wavelength range. Regardless of how much the effective area of cell 12′ is increased through the use of reflective elements and internal reflection, incident radiation falling outside the preferred wavelength range of cell 12′ may be utilized either inefficiently or not at all.

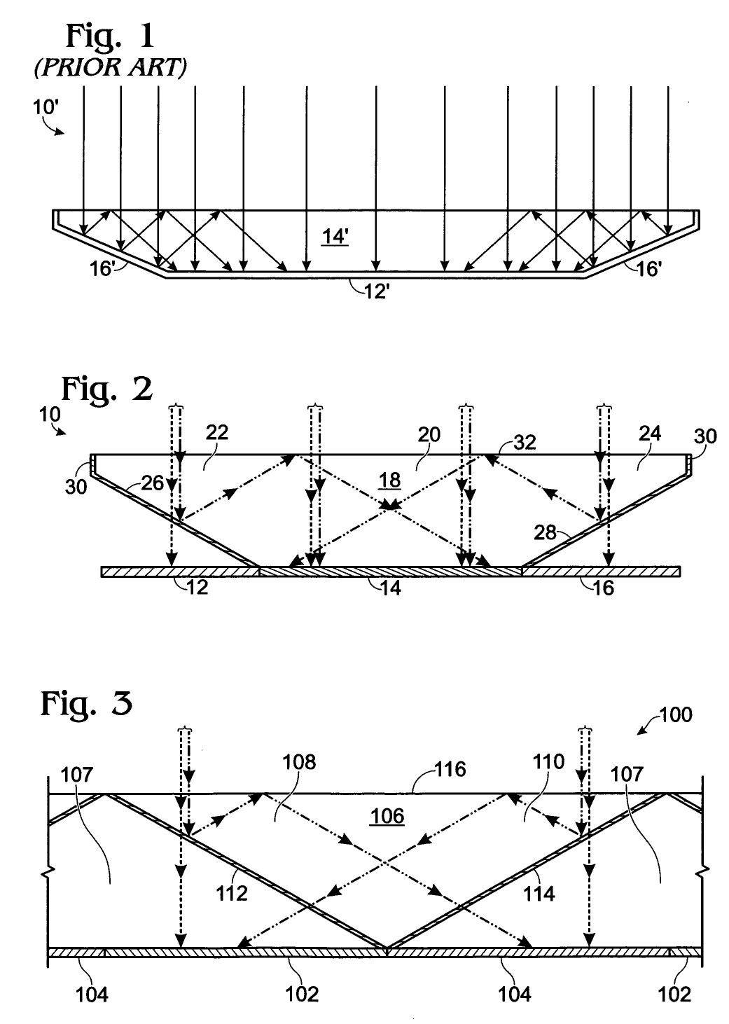

FIG. 2 is a side elevational view of a solar radiation collection system, generally indicated at 10, in accordance with aspects of the present teachings. In system 10, PV cells 12, 14 and 16 are all disposed in proximity to an optical medium 18 having a predetermined index of refraction. It should be appreciated that according to the present teachings, cells 12, 14 and 16 may be disposed in a common plane (as shown in FIG. 2), may mimic the contour of the lower boundary of the medium, or may be arranged in any other suitable manner to collect radiation passing through an appropriate region of medium 18. Specifically, central cell 14 is disposed under a central zone or region 20 of medium 18, so that zone 20 is configured to transmit at least some of the radiation incident on the central zone directly to cell 14. PV cell 12 is disposed under a left-hand zone or region 22, which is disposed at the left-hand side of central zone 20, and zone 22 is configured to transmit some portion of radiation incident on the left-hand zone directly to cell 12. PV cell 16 is disposed under a right-hand zone or region 24 of medium 18, which is disposed at the right-hand side of central zone 20 (opposite zone 22 relative to the central zone), and zone 24 is configured to transmit some portion of radiation incident on the right-hand zone directly to cell 12. In other words, zones 20, 22 and 24 are distinguished by the fact that each zone is configured to transmit some portion of incident radiation directly to the corresponding PV cell.

Dichroic surfaces 26, 28 are respectively disposed at or near lower portions of zones 22 and 24. These surfaces may be formed, for example, by coating the lower boundaries of zones 22 and 24 with an optical coating configured to reflect radiation within a certain range of wavelengths and to transmit radiation within another range of wavelengths, or the dichroic surfaces may be optical elements that are separately formed and then placed within, adjacent to, or in close proximity to zones 22 and 24. In any case, as FIG. 2 indicates, each dichroic surface is configured to reflect a first portion of radiation incident on the corresponding zone of medium 18, and to transmit a second portion of radiation incident on the corresponding zone to the PV cell disposed beneath that zone. The dichroic surfaces may, as in FIG. 2, completely overlap and in some instances extend beyond the corresponding PV cells, or the surfaces may substantially overlap or only partially overlap the corresponding cells.

Radiation transmitted through dichroic surfaces 26, 28 will be at least partially absorbed and transformed to electricity by PV cells 12 and 16, respectively. Radiation reflected by the dichroic surfaces, on the other hand, will arrive at a top boundary 32 of optical medium 18, at which point the reflected radiation will be directed toward central PV cell 14 by internal reflection, provided the reflected rays contact the boundary of medium 18 at or above a sufficient angle to the normal. As described previously, the critical angle is determined by the indices of refraction of optical medium 18 and the surrounding medium, which for solar applications will typically be air or vacuum, each of which has an index of refraction of approximately 1.0. For example, if the system is immersed in air or vacuum and optical medium 18 is constructed from fused silica, which has an index of refraction of around 1.46 over the solar spectrum, at room temperature, then the critical angle is approximately 42 degrees. On the other hand, if medium 18 is constructed from a material with an index of refraction of 3.5 or more (such as germanium), then the critical angle will be less than 17 degrees. Systems with media of a higher index of refraction will in general result in larger acceptance angles due to the resulting greater system etendue.

In some embodiments, PV cells 12, 14 and 16 may be selected to have properties that are correlated with the type of radiation directed toward each particular cell by system 10. For example, PV cell 12 may be configured to convert radiation having wavelengths within a particular wavelength range into electricity, and dichroic surface 26 may be configured to transmit radiation having wavelengths within at least a portion of that same wavelength range to cell 12, and to reflect the remainder of the radiation incident on surface 26. As described above, some or all of this reflected radiation will be directed toward PV cell 14 by internal reflection. Accordingly, cell 14 may be configured to convert into electricity radiation having wavelengths within some or all of the range of wavelengths reflected by surface 26. Similarly, dichroic surface 28 may be configured to transmit wavelengths to PV cell 16 that match the characteristics of cell 16, and to reflect wavelengths toward central cell 14 that match the characteristics of cell 14. In this manner, systems according to the present teachings may be designed to utilize a greater fraction of the incident solar energy than systems that utilize only a single type of PV cell.

A wide variety of configurations of medium 18 fall within the scope of the present teachings. For example, as shown in FIG. 2, side zones 22 and 24 may be disposed substantially symmetrically with respect to central zone 20 of the optical medium, in which case PV cells 12 and 16 may be substantially similar to each other and may be disposed substantially symmetrically around central PV cell 14. Alternatively, the side zones may be disposed asymmetrically around the central zone, and regardless of whether the zones are symmetrically disposed, PV cells 12 and 16 may be dissimilar to each other and configured to respond to different wavelength ranges of radiation.

Central zone 20 may have a substantially rectangular vertical cross section, whereas left-hand zone 22 and right-hand zone 24 each may have a substantially triangular vertical cross section. As depicted in FIG. 2, the substantially triangular cross section of one or both of the outer zones may include an edge portion 30 configured to reduce edge losses by internally reflecting some or all of the radiation that reaches the edge portion. Because medium 18 may be formed by first forming a uniform layer of optical material and then selectively removing material from the PV-facing side of the medium, a planar upper surface may naturally result from the manufacturing process. Accordingly, the central and outer zones of optical medium 18 may jointly define a planar upper surface 32 of medium 18.

FIG. 3 shows a side elevational view of an embodiment of a solar radiation collection system, generally indicated at 100, in which two types of PV cells 102, 104 are disposed under an optical medium 106. As indicated at the edge portions of FIG. 3, the arrangement of PV cells and optical media shown in the central portion of FIG. 3 may be laterally repeated (the same is true for all of the other embodiments of this disclosure). As noted previously, because a single PV cell generally produces only a fraction of a volt, a number of PV cells or collection systems typically must be connected together in electrical series to create a usable voltage. The area under optical medium 106, generally indicated at 107, will typically be air or vacuum.

Focusing on the central portion of FIG. 3, a left-hand zone 108 of optical medium 106 transmits part of the radiation incident on zone 108 directly to left-hand PV cell 102, and a right-hand zone 110 of the optical medium transmits part of the radiation incident on zone 110 directly to right-hand PV cell 104. A first dichroic surface 112 is disposed at or near the lower left-hand boundary of the optical medium and configured to reflect a portion of the radiation incident on zone 108 such that the reflected radiation is directed toward right-hand PV cell 104, and a second dichroic surface 114 is disposed at or near the lower right-hand boundary of the optical medium and configured to reflect a portion of the radiation incident on zone 110 such that the reflected radiation is directed toward left-hand PV cell 102.

In the embodiment of FIG. 3, PV cells 102 and 104 may be chosen to absorb complementary portions of the solar spectrum. For example, cell 102 may be configured to convert radiation within the wavelength range from 300-600 nm into electricity, and cell 104 may be configured to convert radiation within the wavelength range from 600-1200 nm into electricity, although it should be appreciated that these ranges are only exemplary and that any two types of PV cells may be used. To maximize the efficiency of the system, dichroic surface 112 may be configured to transmit the portion of solar spectrum that PV cell 102 is configured to absorb, and to reflect the portion of the spectrum that PV cell 104 is configured to absorb. Similarly, dichroic surface 114 may be configured to transmit the portion of solar spectrum that PV cell 104 is configured to absorb, and to reflect the portion of the spectrum that PV cell 102 is configured to absorb.

As described previously with respect to the embodiment of FIG. 2, some or all of the radiation reflected by dichroic surfaces 112, 114 will be directed toward the opposite PV cell by internal reflection from top boundary 116 of optical medium 106, resulting in each cell receiving more radiation in a particular wavelength range than it would receive in a more conventional arrangement of PV cells. The precise amount of radiation internally reflected at surface 116 will depend upon the angle of inclination of surfaces 112, 144, the angle of incidence of the incoming solar radiation, and the index of refraction of medium 106. In addition, the embodiment shown in FIG. 3 may include outer edge portions (not shown), which may be substantially vertical or otherwise shaped, and which are configured to reduce losses of radiation at the far right-hand and left-hand edges of the system.

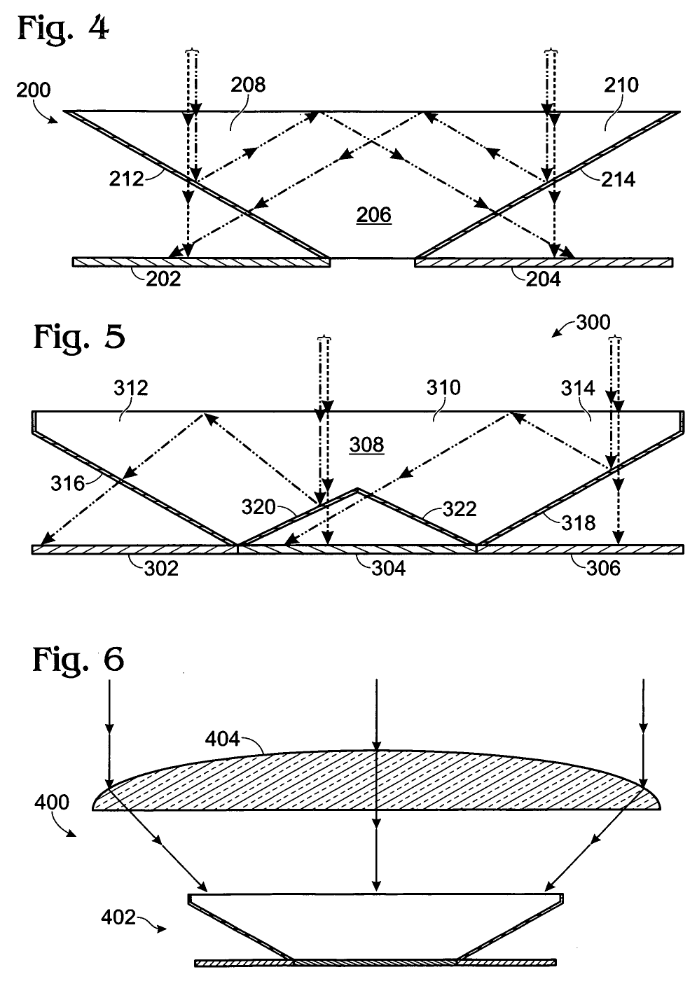

FIG. 4 shows a side elevational view of another embodiment of a solar radiation collection system, generally indicated at 200, in accordance with the present teachings. The embodiment of FIG. 4 is similar to the embodiment of FIG. 3, including a pair of PV cells 202, 204 disposed under an optical medium 206, and a pair of dichroic surfaces 212, 214 respectively disposed under regions 208, 210 of the optical medium. As in the embodiment of FIG. 3, the PV cells and dichroic surfaces shown in FIG. 4 may be configured so that the combination of radiation directly transmitted and internally reflected to each PV cell is significantly greater than it would be in the absence of the optical medium and dichroic surfaces. Unlike the embodiment of FIG. 3, however, FIG. 4 includes a substantially flat central portion at which the optical medium does not overlap an underlying PV cell. This may provide greater stability and ease of manufacture of the system, and also may provide space between PV cells for an electrical connection mechanism to connect adjacent cells.

FIG. 5 shows a side elevational view of yet another embodiment of a solar radiation collection system, generally indicated at 300, in accordance with aspects of the present teachings. System 300 has various features in common with the embodiment of FIG. 2. Specifically, as in the embodiment of FIG. 2, system 300 includes PV cells 302, 304 and 306, each disposed in proximity to an optical medium 308 having a predetermined index of refraction. Central cell 304 is disposed under a central zone or region 310 of medium 308, so that zone 310 is configured to transmit some of the radiation incident on the central zone of the optical medium directly to central cell 304. PV cell 302 is disposed under a left-hand zone or region 312 of medium 308, and zone 312 is disposed to the left-hand side of central zone 310. PV cell 306 is disposed under a right-hand zone or region 314 of medium 308, and zone 314 is disposed to the right-hand side of central zone 310, opposite zone 312 relative to the central zone. To allow direct transmission of incident radiation to the corresponding PV cell, each region of the optical medium may be substantially or entirely overlapping the corresponding cell.

Also as in the embodiment of FIG. 2, dichroic surfaces 316, 318 are respectively disposed at lower portions of zones 312 and 314 in FIG. 5. Each dichroic surface is configured to reflect a portion of radiation incident on the corresponding zone of medium 308, and to transmit another portion of radiation incident on the corresponding zone to the PV cell disposed beneath that zone. In addition, the embodiment of FIG. 5 also includes dichroic surfaces 320, 322 disposed along a lower boundary of central zone 310. Like surfaces 316, 318, each of surfaces 320, 322 is configured to reflect one portion of incident radiation and to transmit another portion. In the case of surfaces 320, 322, the transmitted radiation will pass directly to central PV cell 304. However, by reflecting some portion of radiation incident on central zone 310, radiation not well correlated to the properties of cell 304 may be redirected toward cells 302 and/or 306.

Radiation transmitted through dichroic surfaces 316, 318 will be at least partially absorbed and transformed to electricity by PV cells 302 and 306. Radiation reflected by dichroic surfaces 316, 318 will arrive at a top boundary of optical medium 308, and at least some of the reflected radiation will be directed toward central PV cell 304 by internal reflection, depending upon the angle of the reflected rays to the normal as described before. Similarly, radiation reflected by dichroic surfaces 320, 322, will arrive at a top boundary of medium 308, and will be at least partially directed toward the outer PV cells 302, 306 by internal reflection, again depending upon the angle of incidence of the rays with respect to the normal to the top boundary of the optical medium. The result will be that each of PV cells 302, 304 and 306 receives both directly transmitted radiation and also radiation that has been reflected by one of the dichroic surfaces and then internally reflected within the optical medium.

As in previous embodiments, PV cells 302, 304 and 306 may be configured to absorb and convert into electricity radiation within the wavelength range that will be directed toward each particular cell by the system. For example, central PV cell 304 may be configured to convert solar radiation within a first wavelength range to electricity, and outer PV cells 302, 306 may be configured to convert solar radiation within a second wavelength range into electricity. In that case, outer dichroic surfaces 316, 318 may be configured to transmit solar radiation within the second wavelength range and to reflect solar radiation within the first wavelength range, or at least to transmit and reflect radiation within ranges correlated to the sensitivity ranges of cells 302 and 306. Similarly, inner dichroic surfaces 320, 322 may be configured to transmit solar radiation within at least a portion of the first wavelength range and to reflect solar radiation within at least a portion of the second wavelength range. The overall system thus may be configured to increase the amount of radiation within the appropriate wavelength range that reaches each cell, increasing the efficiency of the system in comparison to conventional systems.

FIG. 6 shows a side elevational view of a solar collection system 400 including a solar collector 402 similar to system 10 of FIG. 2, and also including an optical concentrating element 404 disposed above the solar collector. Collector 402 includes all of the features of system 10, including an optical medium with a predetermined index of refraction, a pair of dichroic surfaces, and PV cells disposed under corresponding regions of the optical medium. The description of these components has been provided previously in the discussion relating to FIG. 2 and will not be repeated here. Optical concentrating element 404, which in FIG. 6 takes the form of a refractive converging lens, is configured to concentrate solar radiation on the optical medium of solar collector 402, so that radiation from a greater surface area than the area of collector 402 itself will reach the optical medium. This concentrated radiation then may be transmitted and/or reflected in the manner described previously with respect to FIG. 2. Furthermore, it should be appreciated that one or more optical concentrating elements such as converging lenses and/or mirrors may be used in conjunction with any of the embodiments of this disclosure, to further increase the production of electricity per unit surface area of the PV material used in the system.

FIG. 7 is a side elevational view showing a plurality of solar collectors formed into a solar collection system 500 in conjunction with a continuous optical medium 502. In one sense, system 500 may be viewed as three collection systems of the type shown in FIG. 2, continuously connected. Specifically, system 500 includes PV cells of two types, which are respectively indicated at 504 and 506. Cells 504 are disposed under “side zones” 508 of optical medium 502, and cells 506 are disposed under “central zones” 510 of optical medium 502. The quotation marks indicate that the some of the “side zones” are in fact closer to the center of FIG. 7 than some of the “central zones.”

In FIG. 7, dichroic surfaces 512 are disposed along the lower boundaries of the “side zones” and configured to transmit one portion of the incident solar radiation and to reflect another portion. Some or all of the reflected radiation will then be directed toward one of the “central zones” 510 by internal reflection from the top boundary of optical medium 502, as has been described previously. As in other embodiments that have described previously and that are contemplated by the present teachings, the PV cells and dichroic surfaces may be configured in a complementary manner, so that each PV cell receives primarily radiation in a wavelength range that the cell is configured to absorb and convert into electricity.

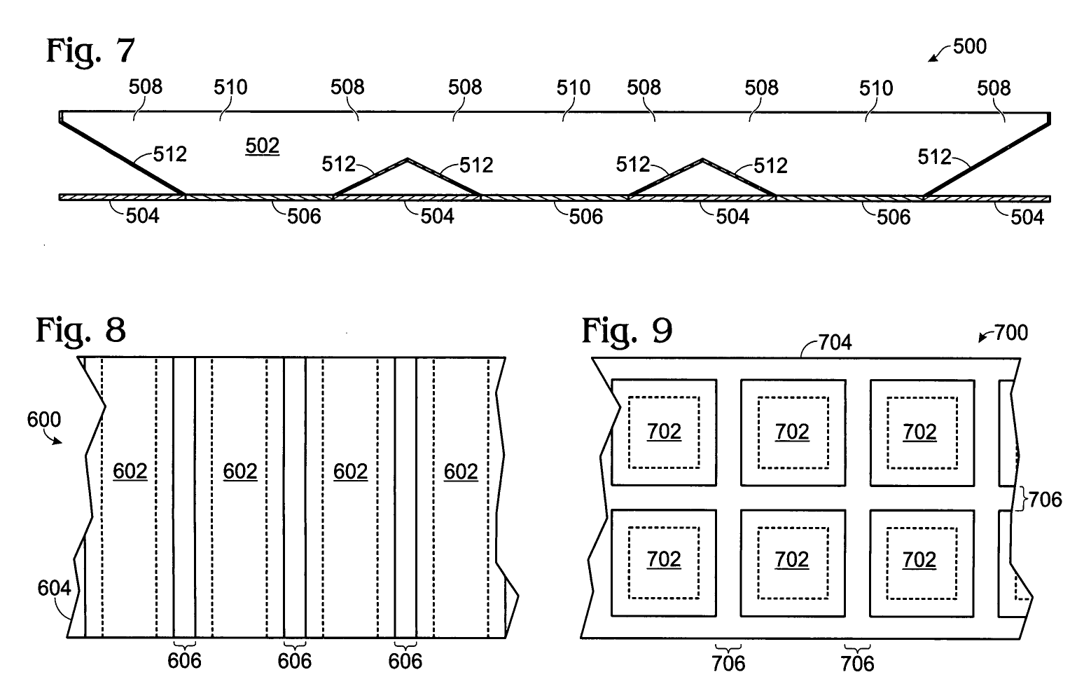

As noted previously, a plurality of PV cells generally must be connected in series to produce a useful voltage, because a typical cell generates only a fraction of a volt. Such a connected set of PV cells is often referred to as a solar collection module or string. FIG. 8 is a top view showing a possible configuration of a solar collection module, generally indicated at 600, including a plurality of solar collectors or collection systems 602 disposed on an underlying substrate 604. The individual collectors 602 each extend substantially along the width of substrate 604, and may be connected in electrical series with conductive tabs or wires (not shown) disposed in gaps 606 provided between collectors 602. Alternatively, the solar collectors may be positioned in closer proximity to each other on the substrate, with little or no gap between adjacent collectors, in which case the PV cells of the module may be electrically connected along the back side of the substrate or in any other suitable manner.

In FIG. 8, each of collectors 602 is depicted as substantially similar to solar collection system 10 shown in FIG. 2. Because system 10 has been described in detail previously, it will not be described again here. However, it should be appreciated that the general module configuration shown in FIG. 8 may be used with any of the embodiments described previously in this disclosure, including in conjunction with optical concentrating elements such as converging lenses. Such lenses or other concentrating elements may be used to offset any gaps that are provided between collectors 602, so that none of the effective area of module 600 is left unused. In other words, FIG. 8 is meant as a non-limiting example of a module configuration in which the solar collectors extend substantially along the width of an underlying substrate.

FIG. 9 is a top view depicting an embodiment of a solar collection module, generally indicated at 700, in which several solar collection systems 702 are disposed on a substrate 704 in a grid or honeycomb configuration. In this embodiment, each solar collection system 702 has a square profile rather than extending along the entire width of the substrate. Accordingly, each solar collection system includes an optical medium having a square-shaped upper surface, with a square-shaped central PV cell disposed under a central portion of the optical medium and a peripheral strip of PV material disposed under a peripheral portion of the optical medium. Gaps 706 may be left between collectors to facilitate their electrical connection. The vertical cross section through the center of the optical medium of each collector in FIG. 9 is substantially similar to the elevational view of system 10 shown in FIG. 2. Again, however, it should be appreciated that various embodiments contemplated by the present teachings may be arranged into grid-type modules, and that optical concentrating elements such as converging lenses may be used to compensate for gaps 706.

The manufacture of each of the systems disclosed previously may be accomplished by various methods. In general, the methods include positioning the various PV cells in predetermined positions relative to each other, positioning an optical medium to transmit at least a portion of the incident solar radiation to each cell, and positioning one or more dichroic surfaces to reflect desired portions of the incident solar radiation such that the reflected portion(s) will be directed toward the appropriate PV cell(s) by internal reflection within the optical medium. As described in detail above, the PV cells of the disclosed systems may be configured to convert solar radiation within a particular wavelength range to electricity, and the dichroic surfaces may be configured to transmit and reflect radiation in an appropriate manner so that each PV cell receives both transmitted and reflected radiation within its optimal wavelength range for electricity generation. The method of manufacture also may include positioning one or more optical concentrating elements, such as refracting lenses, to concentrate solar radiation on the optical medium.

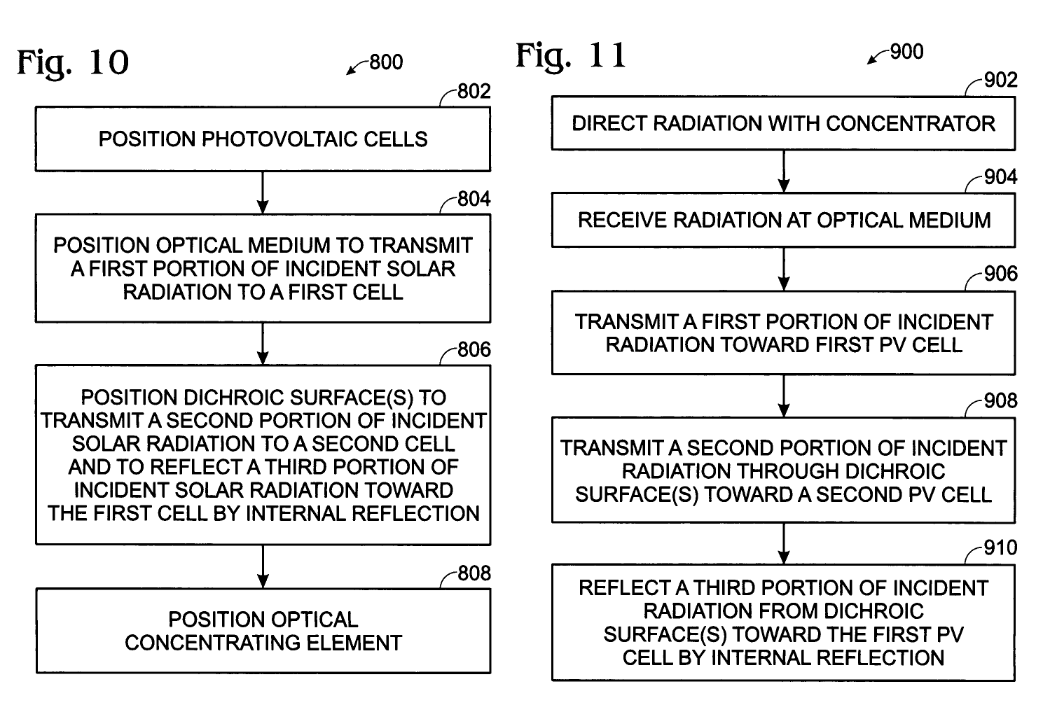

More specifically, FIG. 10 depicts a method of manufacturing solar collection systems, generally indicated at 800, according to aspects of the present teachings. At step 802, two or more PV cells are positioned in predetermined positions relative to each other. The cells may be substantially similar both in size and in the type of radiation they are configured to absorb, or some or all of the cells may differ in both size and composition. At step 804, an optical medium is positioned above the PV cells and in proximity to the cells, so that a first portion of solar radiation incident on the medium will be transmitted directly to a first one of the cells through a region of the medium disposed above the cell. At step 806, a dichroic surface is positioned within, adjacent to, or in proximity to a region of medium disposed above a second one of the cells, to transmit a second portion of solar radiation incident on the medium to the second cell and to reflect a third portion of solar radiation incident on the medium (i.e., the portion reflected by the dichroic surface) such that the third portion is directed toward the first cell by internal reflection within the medium. At step 808, an optical concentrating element is positioned to concentrate radiation toward the optical medium, although it should be appreciated that systems according to the present teachings may be manufactured without an optical concentrating element.

Additional PV cells and/or dichroic surfaces may be positioned as part of the manufacturing process depicted in FIG. 10. For example, step 802 of method 800 may include positioning a third photovoltaic cell in a predetermined position relative to the first and second cells, and step 806 may include positioning a second dichroic surface to transmit a fourth portion of solar radiation incident on the medium to the third cell and to reflect a fifth portion of solar radiation incident on the medium such that the fifth portion is directed toward the first cell by internal reflection within the medium. A system manufactured according to this method, with three PV cells and two dichroic surfaces, may roughly correspond to the system depicted in FIG. 2.

Similarly, in cases where three PV cells have been positioned in step 802, step 806 may include positioning a third dichroic surface (for example, in a region above the first cell) to transmit a sixth portion of solar radiation incident on the medium to the first cell and to reflect a seventh portion of solar radiation incident on the medium such that the seventh portion is directed toward the second cell by internal reflection within the medium, and positioning a fourth dichroic surface (again perhaps above the first cell) to transmit an eighth portion of solar radiation incident on the medium to the first cell and to reflect a ninth portion of solar radiation incident on the medium such that the ninth portion is directed toward the third cell by internal reflection within the medium. The resulting system with three PV cells and four dichroic surfaces may roughly correspond to the system depicted in FIG. 5. It should be appreciated that in this manner, a wide variety of configurations may be constructed using the steps of method 800.

FIG. 11 generally depicts at 900 a method of collecting radiation, such as incident solar radiation, according to the present teachings. At step 902, radiation is directed toward an optical medium by an optical concentrating element such as a converging lens, although as has been described above, radiation may be collected according to the present teachings even in the absence of a dedicated optical concentrating element. At step 904, radiation is received at an optical medium. At step 906, a first portion of the radiation incident on the medium is transmitted toward a first photovoltaic cell. This first portion of radiation is transmitted directly to the first cell, without reflection from another portion of the system. At step 908, a second portion of the radiation incident on the medium is transmitted through a dichroic surface to a second PV cell, and at step 910, a third portion of the radiation incident on the medium is reflected from the dichroic surface such that it is subsequently directed toward the first cell by internal reflection within the medium. It should be understood that steps 908 and 910 represent transmission and reflection of two portions of the radiation that is incident on the dichroic surface, with one portion passing directly to the second PV cell and the other portion reflecting within the waveguide and toward its top surface.

As should be apparent, steps 908 and 910 of method 900 may include transmitting radiation through and reflecting radiation from any desired number of additional dichroic surfaces. In general, transmitted portions will pass directly toward a corresponding PV cell in the direct line of sight of the dichroic surface, whereas reflected portions will be directed toward other PV cells through some degree of internal reflection within the optical medium, such as from its top surface and/or edge portions.

The PV cells used in both manufacturing method 800 and collection method 900 may be of the types described previously, i.e., each cell may be configured to convert radiation within a particular wavelength range to electricity, and these ranges may be correlated to the ranges reflected and transmitted by the various dichroic surfaces. Accordingly, the PV cells used with the all of the disclosed embodiments may be of various types, including those formed on rigid substrates such as rigid silicon-based cells, inorganic thin-film cells formed either on glass or on a flexible substrate (for example, in a roll-to-roll process), or cells based on organic materials. Suitable optical media for use with the present teachings include, for example, materials having indices of refraction in the approximate range of 1.4-2.0, such as fused silica, glass, and various plastics, and also materials having significantly higher indices of refraction, such as germanium. In general, any material that is at least partially transparent to solar radiation and that has an index of refraction significantly higher than 1.0 may be appropriate.

The angled surfaces of the optical medium may be formed by any suitable method, such as with an imprint tool that rolls a film of the optical medium through a patterned roller to imprint the desired pattern on the medium, by injection molding, or by stamping. The PV cells then may be applied to the patterned medium through various deposition methods, or the cells may be manufactured separately, in which case the cells and the medium may be laminated together. Dichroic materials may be applied to the medium either before or after its attachment to the PV cells, for example by vacuum deposition or sputtering through a mask, by a suitable electroplating process, or simply by gluing or otherwise adhering sections of pre-formed dichroic material to desired portions of the medium.

The disclosure set forth above may encompass multiple distinct inventions with independent utility. Although each of these inventions has been disclosed in its preferred form(s), the specific embodiments thereof as disclosed and illustrated herein are not to be considered in a limiting sense, because numerous variations are possible. The subject matter of the inventions includes all novel and nonobvious combinations and subcombinations of the various elements, features, functions, and/or properties disclosed herein. The following claims particularly point out certain combinations and subcombinations regarded as novel and nonobvious. Inventions embodied in other combinations and subcombinations of features, functions, elements, and/or properties may be claimed in applications claiming priority from this or a related application. Such claims, whether directed to a different invention or to the same invention, and whether broader, narrower, equal, or different in scope to the original claims, also are regarded as included within the subject matter of the inventions of the present disclosure.

We claim:

1. A solar radiation collection system comprising:
a first photovoltaic cell;
a second photovoltaic cell; and
an optical medium including:
a first zone configured to transmit radiation incident on the first zone to the first cell;
a second zone disposed adjacent a side of the first zone; and
a first dichroic surface configured to reflect a first portion of radiation incident on the second zone such that the reflected radiation is directed toward the first cell by internal reflection, and to transmit a second portion of radiation incident on the second zone to the second cell.

2. The solar radiation collection system of claim 1, wherein the optical medium further includes a second dichroic surface configured to reflect a first portion of radiation incident on the first zone such that the reflected radiation is directed toward the second cell by internal reflection, and to transmit a second portion of radiation incident on the first zone to the first cell.

3. The solar radiation collection system of claim 1, wherein the first zone has a substantially rectangular cross section, the second zone has a substantially triangular cross section, and the first and second zones jointly define a planar upper surface of the optical medium.

4. The solar radiation collection system of claim 1, wherein the first cell is configured to convert radiation within a first wavelength range into electricity, the second cell is configured to convert radiation within a second wavelength range into electricity, and the first dichroic surface is configured to reflect radiation having wavelengths within at least a portion of the first wavelength range and to transmit radiation having wavelengths within at least a portion of the second wavelength range.

5. The solar radiation collection system of claim 1, further comprising a third photovoltaic cell and wherein the optical medium further includes:
a third zone disposed at a side of the first zone opposite the side at which the second zone is disposed; and
a second dichroic surface configured to reflect a first portion of radiation incident on the third zone such that the reflected radiation is directed toward the first cell by internal reflection, and to transmit a second portion of radiation incident on the third zone to the third cell.

6. The solar radiation collection system of claim 5, wherein the third cell is substantially similar to the second cell, and the second and third zones are disposed substantially symmetrically about the first zone.

7. The solar radiation collection system of claim 5, wherein the optical medium further includes:
a third dichroic surface configured to reflect a first portion of radiation incident on the first zone such that the reflected radiation is directed toward the second cell by internal reflection, and to transmit a second portion of radiation incident on the first zone to the first cell; and
a fourth dichroic surface configured to reflect a third portion of radiation incident on the first zone such that the reflected radiation is directed toward the third cell by internal reflection, and to transmit a fourth portion of radiation incident on the first zone to the first cell.

8. The solar radiation collection system of claim 7, wherein the third cell is substantially similar to the second cell, the third and fourth dichroic surfaces are disposed substantially symmetrically along a boundary of the first zone, and the second and third zones are disposed substantially symmetrically about the first zone.

9. The solar radiation collection system of claim 1, wherein the second zone includes an edge portion configured to internally reflect incident solar radiation to reduce edge losses.

10. A method of manufacturing a solar radiation collection system, comprising:
positioning first and second photovoltaic cells in predetermined positions relative to each other;
positioning an optical medium to transmit a first portion of solar radiation incident on the medium to the first cell; and
positioning a first dichroic surface to transmit a second portion of solar radiation incident on the medium to the second cell and to reflect a third portion of solar radiation incident on the medium such that the third portion is directed toward the first cell by internal reflection within the medium.

11. The method of claim 10, wherein the first cell is configured to convert solar radiation within a first wavelength range to electricity, and the second cell is configured to convert solar radiation within a second wavelength range to electricity.

12. The method of claim 10, further comprising:
positioning a third photovoltaic cell in a predetermined position relative to the first and second cells; and
positioning a second dichroic surface to transmit a fourth portion of solar radiation incident on the medium to the third cell and to reflect a fifth portion of solar radiation incident on the medium such that the fifth portion is directed toward the first cell by internal reflection within the medium.

13. The method of claim 12, wherein the first cell is configured to convert solar radiation within a first wavelength range to electricity, the second cell is configured to convert solar radiation within a second wavelength range to electricity, and the third cell is configured to convert solar radiation within a third wavelength range to electricity.

14. The method of claim 12, further comprising:
positioning a third dichroic surface to transmit a sixth portion of solar radiation incident on the medium to the first cell and to reflect a seventh portion of solar radiation incident on the medium such that the seventh portion is directed toward the second cell by internal reflection within the medium; and
positioning a fourth dichroic surface to transmit an eighth portion of solar radiation incident on the medium to the first cell and to reflect a ninth portion of solar radiation incident on the medium such that the ninth portion is directed toward the third cell by internal reflection within the medium.

15. The method of claim 10, further comprising positioning an optical concentrating element to concentrate radiation toward the optical medium.

16. A method of collecting solar radiation, comprising:
receiving radiation at an optical medium;
transmitting a first portion of the radiation incident on the medium toward a first photovoltaic cell;
transmitting a second portion of the radiation incident on the medium through a first dichroic surface toward a second photovoltaic cell; and
reflecting a third portion of the radiation incident on the medium from the first dichroic surface such that the third portion is directed toward the first cell by internal reflection within the medium.

17. The method of claim 16, wherein the first cell is configured to convert solar radiation within a first wavelength range to electricity, and the second cell is configured to convert solar radiation within a second wavelength range to electricity.

18. The method of claim 16, further comprising:
transmitting a fourth portion of the radiation incident on the medium through a second dichroic surface to a third photovoltaic surface; and
reflecting a fifth portion of the radiation incident on the medium from the second dichroic surface such that the fifth portion is directed toward the first cell by internal reflection within the medium.

19. The method of claim 18, wherein the first cell is configured to convert solar radiation within a first wavelength range to electricity, the second cell is configured to convert solar radiation within a second wavelength range to electricity, and the third cell is configured to convert solar radiation within a third wavelength range to electricity.

20. The method of claim 16, further comprising directing the radiation from an optical concentrating element toward the optical medium.
